(19) United States
(12) Patent Application Publication
(10) Pub. No.: US 2006/0281299 A1
(43) Pub. Date: Dec. 14, 2006

(54) METHOD OF FABRICATING SILICON CARBIDE-CAPPED COPPER DAMASCENE INTERCONNECT

(76) Inventors: Jei-Ming Chen, Taipei Hsien (TW); Chin-Hsiang Lin, Hsin-Chu City (TW); Chih-Chien Liu, Taipei City (TW); Kuo-Chih Lai, Tai-Nan City (TW)

Correspondence Address: NORTH AMERICA INTELLECTUAL PROPERTY CORPORATION, P.O. BOX 506, MERRIFIELD, VA, 22116, US

(21) Appl. No.: 11/462,045

(22) Filed: Aug. 3, 2006

Related U.S. Application Data
(63) Continuation-in-part of application No. 10/711,015, filed on Aug. 18, 2004.

(51) Int. Cl. H01L 21/4763; H01L 23/48

(52) U.S. Cl. 438/622; 257/774

(57) ABSTRACT

A dielectric layer overlying a substrate is prepared. A damascene opening is etched into the dielectric layer. The damascene opening is filled with copper or copper alloy. A surface of the copper or copper alloy is treated with hydrogen-containing plasma such as H₂ or NH₃ plasma. The treated surface of the copper or copper alloy then reacts with trimethylsilane or tertramethylsilane under plasma enhanced chemical vapor deposition (PECVD) conditions. Subsequently, by PECVD, a silicon carbide layer is in-situ deposited on the copper or copper alloy.

### CROSS REFERENCE TO RELATED APPLICATIONS

This application is a continuation-in-part of U.S. application Ser. No. 10/711,015 filed Aug. 18, 2004.

### BACKGROUND OF THE INVENTION

1. Field of the Invention

The present invention relates to semiconductor processes, and more particularly to copper damascene interconnect in semiconductor devices with a silicon carbide capping layer.

2. Description of the Prior Art

Copper dual damascene architectures with low-k dielectrics are developing and becoming the norm now in forming interconnects in the back-end of line (BEOL) processes. As design rules are scaled down into the deep sub-micron range, the reliability of copper damascene interconnects becomes increasingly significant. It is known that the silicon nitride (SiN) capping layer exhibits poor adhesion to the copper or copper alloy surface. It is also known that conventional practices in forming a copper or copper alloy interconnect member in a damascene opening, results in the formation of a thin copper oxide comprising a mixture of CuO and Cu₂O. It is believed that such a thin copper oxide forms during chemical mechanical polishing (CMP).

The presence of such a thin copper oxide film undesirably reduces the adhesion of a SiN capping layer to the underlying copper or copper alloy interconnect member. Consequently, cracks are generated at the copper/copper oxide interface, thereby resulting in copper diffusion and increased electromigration as a result of such copper diffusion. The cracks occurring in the copper/copper oxide interface enhance surface diffusion which is more rapid than grain boundary diffusion or lattice diffusion.

The aforesaid problems associated with the copper damascene technologies were addressed by Ngo et al. in U.S. Pat. No. 6,211,084 filed Jul. 9, 1998, entitled “Method of forming reliable copper interconnects”; in U.S. Pat. No. 6,303,505 filed Jul. 9, 1998, entitled “Copper interconnect with improved electromigration resistance”; and also in U.S. Pat. No. 6,492,266 filed Jul. 9, 1998, entitled “Method of forming reliable capped copper interconnects”.

In U.S. Pat. No. 6,211,084, Ngo et al. teach a method including electroplating or electroless plating Cu or a Cu alloy to fill a damascene opening in a dielectric interlayer, chemical mechanical polishing, treating the exposed surface of the Cu or Cu alloy interconnect member in a silane or dichlorosilane plasma to form the copper silicide layer and depositing a SiN capping layer thereon.

In U.S. Pat. No. 6,303,505, Ngo et al. teach a method including electroplating or electroless plating Cu or a Cu alloy to fill a damascene opening in a dielectric layer, chemical-mechanical polishing, hydrogen plasma treatment, reacting the treated surface with silane or dichlorosilane to form a layer of copper silicide on the treated surface and depositing a SiN capping layer on the thin copper silicide layer.

In U.S. Pat. No. 6,492,266, Ngo et al. teach a method including electroplating or electroless plating Cu to fill a damascene opening in a dielectric interlayer, chemical mechanical polishing, then treating the exposed surface of the Cu interconnect to form the copper silicide layer thereon, and depositing a SiN capping layer on the copper silicide layer. The adhesion of the SiN capping layer to the Cu interconnect member is enhanced by treating the exposed surface of the Cu interconnect member: (a) under plasma conditions with ammonia and silane or dichlorosilane to form a copper silicide layer thereon; or (b) with an ammonia plasma followed by reaction with silane or dichlorosilane to form a copper silicide layer thereon.

There is a constant need in this industry to provide a more reliable copper dual damascene interconnect methodology.

### SUMMARY OF THE INVENTION

The primary object of the present invention is to provide a reliable copper damascene process for manufacturing semiconductor devices with a silicon carbide capping layer.

According to the claimed invention, a copper damascene process is disclosed. A dielectric layer overlying a substrate is prepared. A damascene opening is etched into the dielectric layer. The damascene opening is filled with copper or copper alloy. A surface of the copper or copper alloy is treated with hydrogen-containing plasma such as H₂ or NH₃ plasma. The treated surface of the copper or copper alloy then reacts with trimethylsilane or tertramethylsilane under plasma enhanced chemical vapor deposition (PECVD) conditions. Subsequently, by PECVD, a silicon carbide layer is in-situ deposited on the copper or copper alloy.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIGS. 1-5 schematically illustrates a preferred embodiment of the present invention;

FIG. 6 is a flow chart illustrating one preferred embodiment of the present invention; and

FIG. 7 is a flow chart illustrating another preferred embodiment of the present invention.

### DETAILED DESCRIPTION

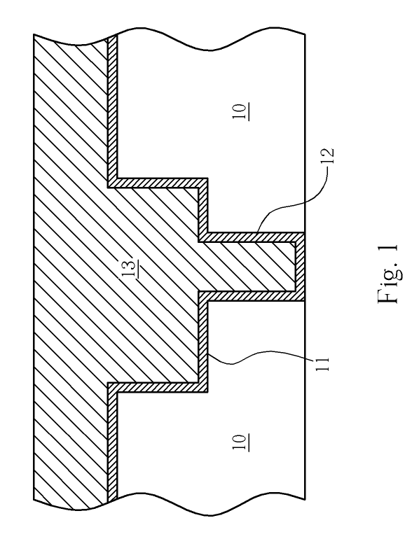

FIGS. 1-5 schematically illustrates one preferred embodiment of the present invention, wherein similar reference numerals denote similar features. Referring to FIG. 1, recessed opening 11 is formed in interlayer dielectric 10. The interlayer dielectric 10 may be made of silicon dioxide, low-k materials or the like. The opening 11 is formed as a dual damascene opening comprising a contact or via hole in communication with a trench opening. It is understood that opening 11 can be formed as a single damascene opening. A diffusion barrier 12 is deposited. The diffusion barrier 12 can be, but are not limited to, tantalum (Ta), tantalum nitride (TaN), titanium nitride (TiN), titanium-tunigsteni (TiW), tungsten (W), tungsten nitride (WN), Ti/TiN, titanium silicon nitride (TiSiN), tungsten silicon nitride (WSiN), tantalum silicon nitride (TaSiN) and silicon nitride. Copper or a copper alloy layer 13 is then deposited using electroplating or electroless methods known in the art. Typically, upon electroplating or electroless plating layer 13, a seed layer (not shown) is deposited on the diffusion barrier 12.

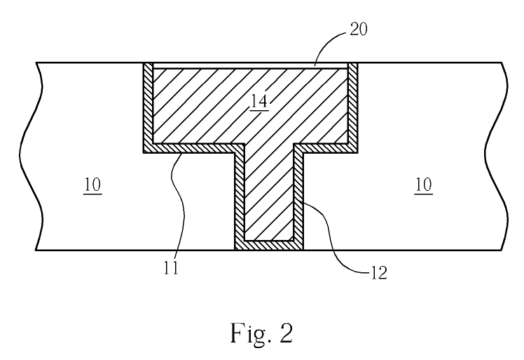

Referring to FIG. 2, the portions of the copper or copper alloy layer 13 extending beyond opening 11 are removed by chemical mechanical polishing (CMP). A thin film of copper oxide 20 is formed on the exposed surface of the copper or copper alloy interconnect member 14. The thin copper oxide 20 may comprise a mixture of CuO and Cu₂O.

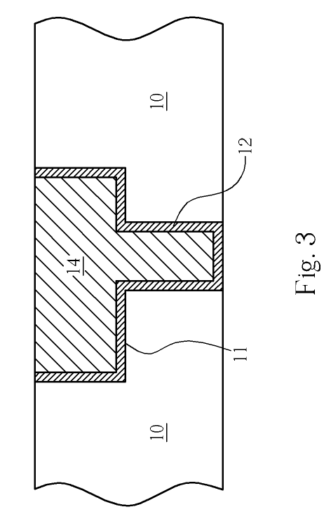

Referring to FIG. 3, a reduction process is carried out. In accordance with the preferred embodiment of the present invention, the exposed surface of the copper or copper alloy interconnect member 14 having a thin copper oxide film 20 thereon is treated with an hydrogen plasma or ammonia plasma to remove or substantially reduce the thin copper oxide film 20 leaving a clean reduced copper or copper alloy surface 30.

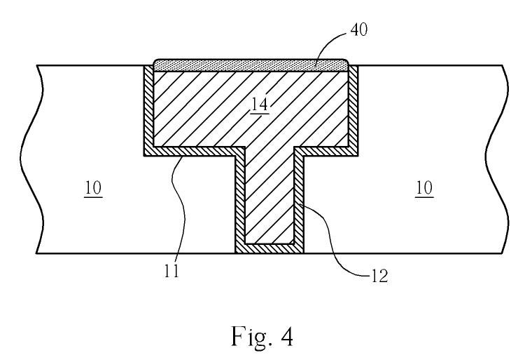

Referring to FIG. 4, prior to capping of the surface-reduced copper or copper alloy interconnect member 14, the cleaned surface 30 of copper or copper alloy interconnect 14 is pre-treated by reaction with precursors selected from the group consisting of trimethylsilane, tertramethylsilane and a mixture of trimethylsilane and tertramethylsilane in a plasma-enhanced chemical vapor deposition (PECVD) tool. A copper silicide layer 40 is formed. According to the preferred embodiment, the pre-treatment comprises the following processing parameters: a trimethylsilane (or tertramethylsilane) gas flow in the range of 100 to 5000 sccm, preferably 300 to 1000 sccm; a process temperature in the range of 300° C. to 450° C., preferably 350° C. to 400° C.; and a reaction duration in the range of 0.1 seconds to 30 seconds, preferably 0.3 seconds to 10 seconds. The order of the pre-treatment process in the PECVD tool may be (1) first supplying trimethylsilane (or tertramethylsilane) gas, then initiating plasma; or (2) supplying trimethylsilane (or tertramethylsilane) gas and initiating plasma simultaneously. Nevertheless, the later is more preferably and more effective because it has at least the advantages including but not limited to (1) The quality of the copper silicide layer 40 is better because the Si—N and/or Si—H bonding of the trimethylsilane or tertramethylsilane molecules are promptly broken before adsorbed onto the wafer surface to be pre-treated with the presence of initiated plasma. (2) Particle problem is alleviated with the presence of initiated plasma when trimethylsilane or tertramethylsilane is introduced into the reaction chamber to react with the copper surface.

If the plasma is not turned on upon the introduction of trimethylsilane or tertramethylsilane, the introduced trimethylsilane or tertramethylsilane molecules will be adsorbed onto the wafer surface and not react with the copper. Even if later on the plasma is turned on, the reaction performance is poor. In other words, the simultaneous introduction of trimethylsilane or tertramethylsilane and ignition of plasma can improve the reaction of the trimethylsilane or tertramethylsilane with the copper, and reduce the consumption of introduced trimethylsilane or tertramethylsilane.

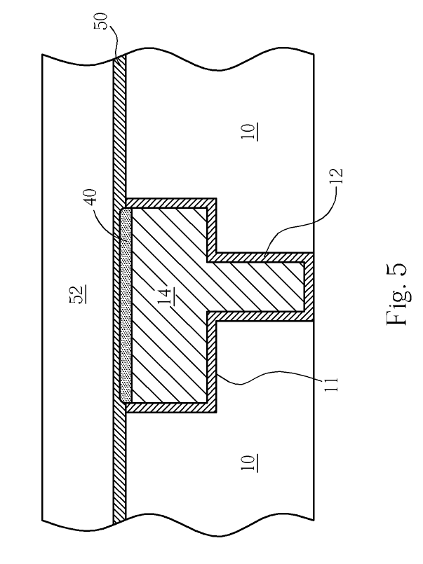

Referring FIG. 5, a silicon carbide (SiC) capping layer 50 is then in-situ deposited using the same PECVD tool so as to completely encapsulate the copper or copper alloy interconnect 14. The methodology disclosed in U.S. Pat. No. 6,365,527, which is assigned to the same party as the present application, is preferably employed to implement formation of SiC capping layer 50. Another dielectric layer or interlayer 52 is then deposited. It is advantageous to use silicon carbide as the capping material because silicon carbide formed by PECVD, possessing a low dielectric constant and high resistivity, has become a potential substitute for silicon nitride in semiconductor integrated circuits fabrication. As device technology leads to smaller and smaller geometries, the development of the silicon carbide film is believed to be one solution for resolving RC delay during IC fabrication.

A PECVD silicon carbide film is deposited from gaseous organosilicon such as silane/methane, dimethylsilane, trimethylsilane or tertramethylsilane. The deposition may be carried out in a single step or in multiple steps. The PECVD film generally contains large amounts of bonded hydrogen in the form of Si—H and C—H, and the composition of which is thus represented as SiCxHy. The carbide material is found to exhibit excellent insulating properties, such as low dielectric constant (in the range of 4-5) and high resistivity towards copper diffusion. As a result, a PECVD silicon carbide film is an excellent choice other than nitride for making insulators such as copper barrier during IC fabrication.

According to this invention, a PECVD process using silane/methane, bimethylsilane, trimethylsilane, tertramethylsilane or other organosilicon precursor gas and N₂, Ar or He as carrier gas is performed to deposit the SiC capping layer 50. Following the carbide deposition, the deposit is treated with an in-situ ammonia plasma. The ammonia plasma treatment comprises the following processing parameters: an ammonia gas flow in the range of 2500 to 5000 sccm; a nitrogen flow in the range of 1000 to 3000 sccm; a PF power density in the range of 0.5 to 1.5 W/cm²; and a chamber pressure ranging from 3 to 5 Torr. Depending on the carbide deposited thickness the plasma treatment lasts generally from 5 to 20 seconds. During the plasma treatment, the H atoms dissociated from ammonia plasma tend to diffuse into the carbide film at a temperature higher than 400° C. and carry out the excess oxygen atoms from the carbide deposit in the form of H₂O molecules. As such, the oxygen content of the silicon carbide material is effectively reduced. The PECVD SiC capping layer 50 with reduced oxygen substance alleviates copper oxidation and thus largely decrease resistance of the copper interconnect.

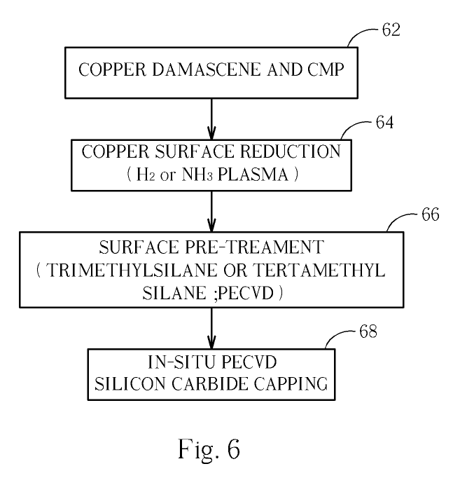

Referring to FIG. 6, a flow chart in accordance with one preferred embodiment of the present invention is demonstrated. In Step 62, copper damascene or dual damascene process is carried out to form copper interconnect members on a semiconductor wafer. The wafer is then subjected to CMP. In Step 64, the exposed surface of the copper or copper alloy interconnect member having a thin copper oxide film thereon is treated with an hydrogen plasma or ammonia plasma to remove or substantially reduce the thin copper oxide film leaving a clean reduced copper or copper alloy surface. In Step 66, prior to capping the copper or copper alloy surface, the clean reduced copper or copper alloy surface is pre-treated with by reaction with precursors selected from the group consisting of trimethylsilane, tertramethylsilane and a mixture of trimethylsilane and tertramethylsilane in a plasma-enhanced chemical vapor deposition (PECVD) tool. In Step 68, silicon carbide (SiC) capping layer is then in-situ deposited to completely encapsulate the copper or copper alloy interconnect.

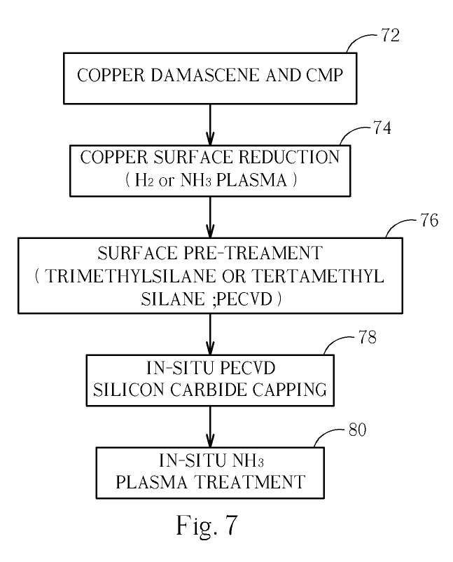

Referring to FIG. 7, a flow chart in accordance with another preferred embodiment of the present invention is demonstrated. In Step 72, copper damascene or dual damascene process is carried out to form copper interconnect members on a semiconductor wafer. The wafer is then subjected to CMP. In Step 74, the exposed surface of the copper or copper alloy interconnect member having a thin copper oxide film thereon is treated with an hydrogen plasma or ammonia plasma to remove or substantially reduce the thin copper oxide film leaving a clean reduced copper or copper alloy surface. In Step 76, prior to capping the copper or copper alloy surface, the clean reduced copper or copper alloy surface is pre-treated with by reaction with precursors selected from the group consisting of trimethylsilane, tertramethylsilane and a mixture of trimethylsilane and tertramethylsilane in a plasma-enhanced chemical vapor deposition (PECVD) tool. In Step 78, SiC capping layer is then in-situ deposited to completely encapsulate the copper or copper alloy interconnect. In Step 80, the SiC capping layer is treated with an in-situ ammonia plasma.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A copper damascene process, comprising:
forming a dielectric layer overlying a substrate;
etching a damascene opening into said dielectric layer;
filling said damascene opening with copper or copper alloy;
treating a surface of said copper or copper alloy with hydrogen-containing plasma;
reacting said treated surface of said copper or copper alloy under plasma enhanced chemical vapor deposition (PECVD) conditions comprising simultaneously supplying trimethylsilane or tertramethylsilane and initiating plasma to make said trimethylsilane or tertramethylsilane react with said treated surface of said copper or copper alloy; and
in-situ depositing, by PECVD, a silicon carbide layer capping on said copper or copper alloy.

2. The copper damascene process according to claim 1 further comprising:
lining said damascene opening with a diffusion barrier layer;
forming a seed layer on said diffusion barrier layer; and
forming said copper or copper alloy on said seed layer.

3. The copper damascene process according to claim 1 wherein said damascene opening comprises a contact or via hole in communication with a trench opening.

4. The copper damascene process according to claim 1 wherein the step of reacting said treated surface of said copper or copper alloy with trimethylsilane or tertramethylsilane comprises following processing parameters: a trimethylsilane (or tertramethylsilane) gas flow in the range of 100 to 5000 sccm; a process temperature in the range of 300° C. to 450° C.; and a reaction duration in the range of 0.1 seconds to 30 seconds.

5. A copper damascene process, comprising:
forming a dielectric layer overlying a substrate;
etching a damascene opening into said dielectric layer;
filling said damascene opening with copper or copper alloy;
treating a surface of said copper or copper alloy with hydrogen-containing plasma;
reacting said treated surface of said copper or copper alloy under plasma enhanced chemical vapor deposition (PECVD) conditions comprising simultaneously supplying trimethylsilane or tertramethylsilane and initiating plasma to make said trimethylsilane or tertramethylsilane react with said treated surface of said copper or copper alloy; and
in-situ depositing, by PECVD, a silicon carbide layer capping on said copper or copper alloy, said silicon carbide layer being treated with in-situ ammonia plasma to remove contained oxygen of the deposited layer.

6. The copper damascene process according to claim 5 further comprising:
lining said damascene opening with a diffusion barrier layer;
forming a seed layer on said diffusion barrier layer; and
forming said copper or copper alloy on said seed layer.

7. The copper damascene process according to claim 5 wherein said damascene opening comprises a contact or via hole in communication with a trench opening.

8. The copper damascene process according to claim 5 wherein the step of reacting said treated surface of said copper or copper alloy with trimethylsilane or tertramethylsilane comprises following processing parameters: a trimethylsilane (or tertramethylsilane) gas flow in the range of 100 to 5000 sccm; a process temperature in the range of 300° C. to 450° C.; and a reaction duration in the range of 0.1 seconds to 30 seconds.
